(19) United States
(12) Patent Application Publication
(10) Pub. No.: US 2026/0229860 A1
(43) Pub. Date: Aug. 6, 2026

(54) WIRE HARNESS

(71) Applicant: Yazaki Corporation, Tokyo (JP)

(72) Inventors: Katsunori SATO, Shizuoka (JP); Tatsuya OGA, Shizuoka (JP)

(73) Assignee: Yazaki Corporation, Tokyo (JP)

(21) Appl. No.: 19/574,654

(22) Filed: Mar. 23, 2026

Related U.S. Application Data
(63) Continuation of application No. PCT/JP2025/004310, filed on Feb. 10, 2025.

(30) Foreign Application Priority Data
Mar. 14, 2024 (JP) 2024-039918

(51) Int. Cl. H02G 3/04; H05K 1/02

(52) U.S. Cl. CPC H02G 3/0418; H05K 1/028; H05K 2201/055

(57) ABSTRACT

A wire harness includes: a flat wiring member formed in a U shape and including a first portion, a second portion, and an intermediate portion connecting an end of the first portion and an end of the second portion to each other; a first case that holds the first portion; a second case that holds the second portion; a rotating structure that couples the first case and the second case to each other so as to be able to rotate relative to each other; and a space portion provided in the second case. The flat wiring member having a straight line shape has a first folded portion and a second folded portion. The space portion accommodates an extra length that occurs in the second portion when the first case and the second case rotate relative to each other while forming a second folded portion.

### CROSS-REFERENCE TO RELATED APPLICATION

This application is a continuation application of International Application No. PCT/JP2025/004310 filed on February 10, 2025 which claims the benefit of priority from Japanese Patent Application No. 2024-039918 filed on March 14, 2024 and designating the U.S., the entire contents of which are incorporated herein by reference.

### BACKGROUND OF THE INVENTION

### 1. Field of the Invention

The present invention relates to a wire harness.

### 2. Description of the Related Art

There are conventionally known flat wiring members such as a flexible printed circuit board. JP 2015-170699 A discloses a flexible printed circuit board capable of easily implementing elongated wire arrangement. The flexible printed circuit board of JP 2015-170699 A includes: a first band-shaped member and a second band-shaped member each having a conductive portion and an insulating portion covering the conductive portion; and a first coupling member that couples a first end of the first band-shaped member and a first end of the second band-shaped member to each other.

The flat wiring member formed in a U shape is desired to be elongated into a straight line shape. When the flat wiring member formed in the U shape is used, the manufacturing cost and the mounting cost of the flat wiring member can be reduced. Here, in a case where an extra length occurs when the flat wiring member is transformed into a straight line shape, it is desirable that stress associated with the occurrence of the extra length can be relaxed.

### SUMMARY OF THE INVENTION

An object of the present invention is to provide a wire harness capable of elongating a flat wiring member formed in a U shape into a straight line shape and capable of relaxing stress associated with occurrence of extra length.

In order to achieve the above mentioned object, a wire harness according to one aspect of the present invention includes: a flat wiring member formed in a U shape, the flat wiring member including a first portion having a straight line shape, a second portion having a straight line shape, and an intermediate portion connecting an end of the first portion and an end of the second portion to each other; a first case that holds the first portion; a second case that holds the second portion; a rotating structure that couples the first case and the second case to each other so as to be able to rotate relative to each other; and a space portion provided in the second case, wherein the first case and the second case can be engaged with each other in a state where the flat wiring member has a straight line shape, the flat wiring member having a straight line shape has a configuration in which the second portion extends on an extension line of the first portion in plan view, the flat wiring member having a straight line shape includes a first folded portion and a second folded portion, the intermediate portion is folded along a folding line in the first folded portion, the folding line extending in an extending direction in which the first portion extends, the second portion is folded, in the second folded portion, along a folding line orthogonal to the extending direction so as to allow a part of the second portion to overlap with the intermediate portion, the rotating structure is configured to form the second folded portion in the second portion by rotating the first case and the second case relative to each other, and the space portion accommodates an extra length that occurs in the second portion when the first case and the second case rotate relative to each other while forming the second folded portion.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view of a wire harness according to an embodiment;

FIG. 2 is a perspective view of a flat wiring member according to the embodiment;

FIG. 3 is a plan view of the flat wiring member according to the embodiment;

FIG. 4 is a plan view of a case according to the embodiment;

FIG. 5 is a perspective view of the case according to the embodiment;

FIG. 6 is a plan view of the wire harness according to the embodiment;

FIG. 7 is a plan view of the wire harness according to the embodiment;

FIG. 8 is a plan view of the wire harness according to the embodiment;

FIG. 9 is a cross-sectional view of the wire harness according to the embodiment;

FIG. 10 is a perspective view of the flat wiring member according to the embodiment;

FIG. 11 is a cross-sectional view of the wire harness according to the embodiment;

FIG. 12 is a perspective view illustrating a second rotation step;

FIG. 13 is a cross-sectional view of the wire harness according to the embodiment;

FIG. 14 is a cross-sectional view of the wire harness according to the embodiment;

FIG. 15 is a perspective view illustrating an example of a holding structure according to the embodiment;

FIG. 16 is a cross-sectional view illustrating an example of the holding structure according to the embodiment; and

FIG. 17 is a cross-sectional view illustrating an example of the holding structure according to the embodiment.

### DETAILED DESCRIPTION OF THE PREFERRED EMBODIMENTS

Hereinafter, a wire harness according to an embodiment of the present invention will be described in detail with reference to the drawings. Note that the present invention is not limited by the embodiment. Moreover, components in the following embodiment include those that are easily conceivable for those skilled in the art or substantially identical.

### Embodiment

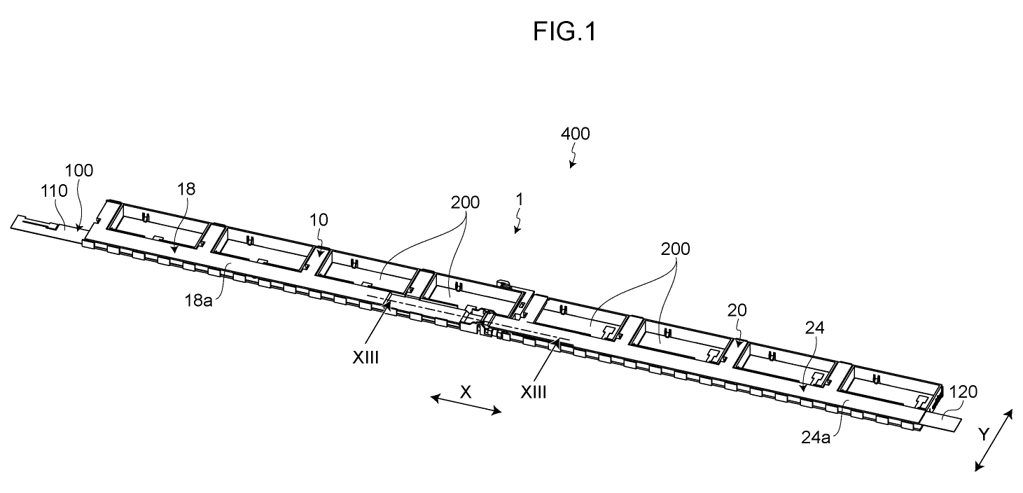

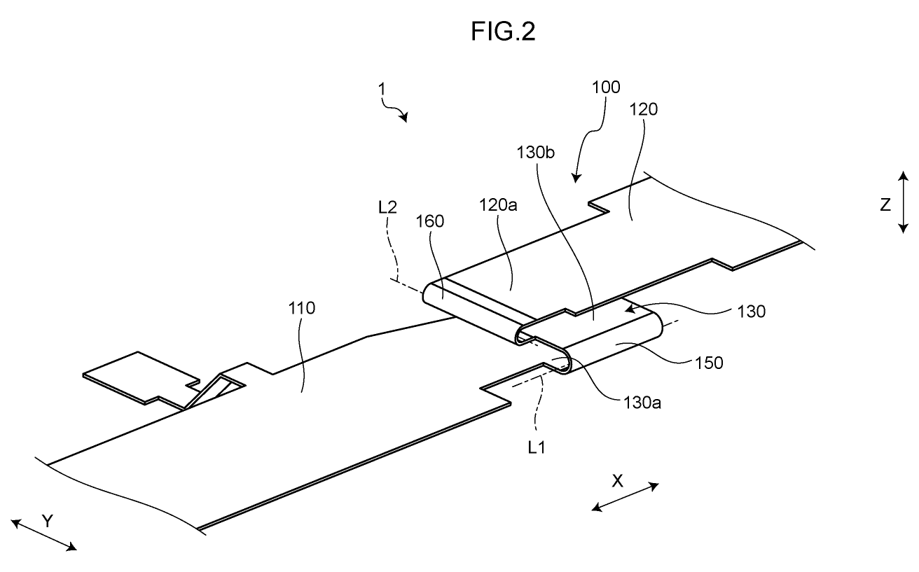

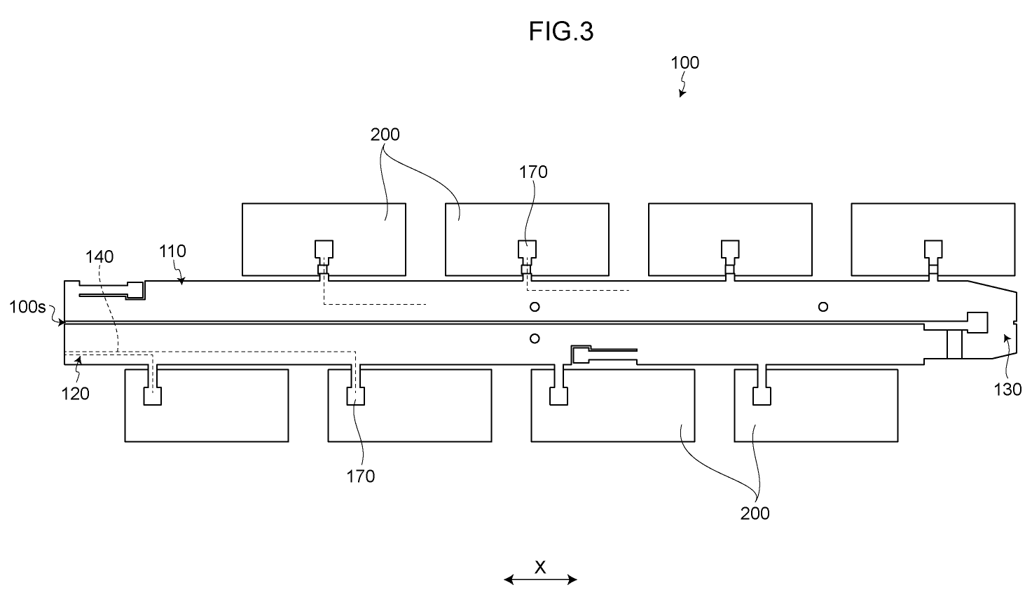

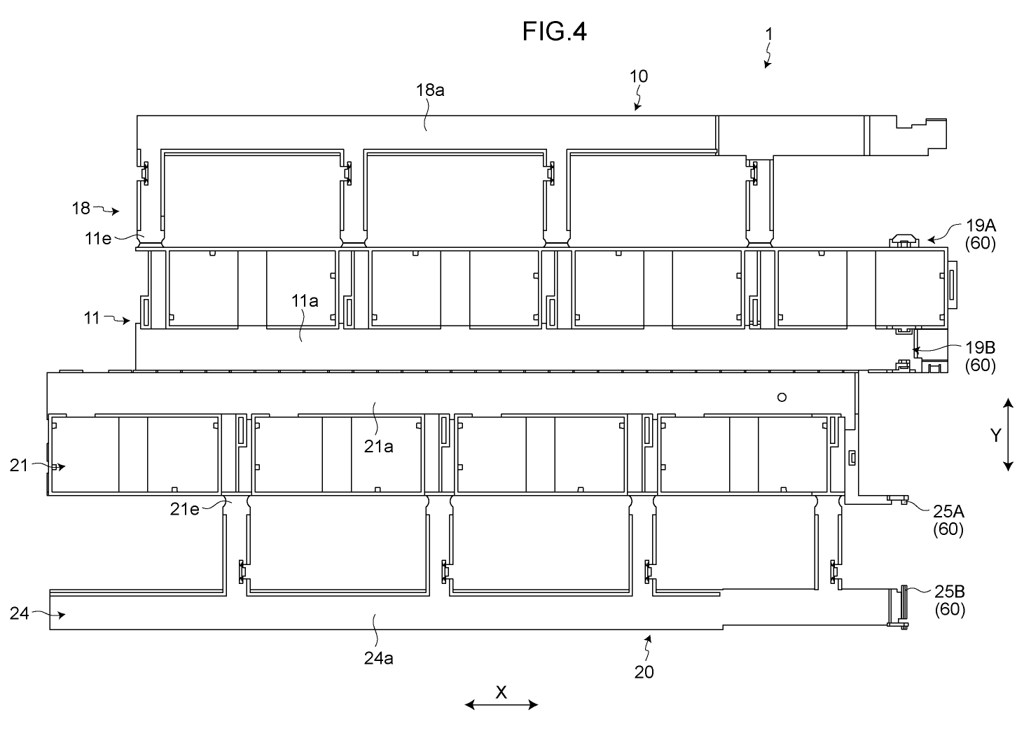

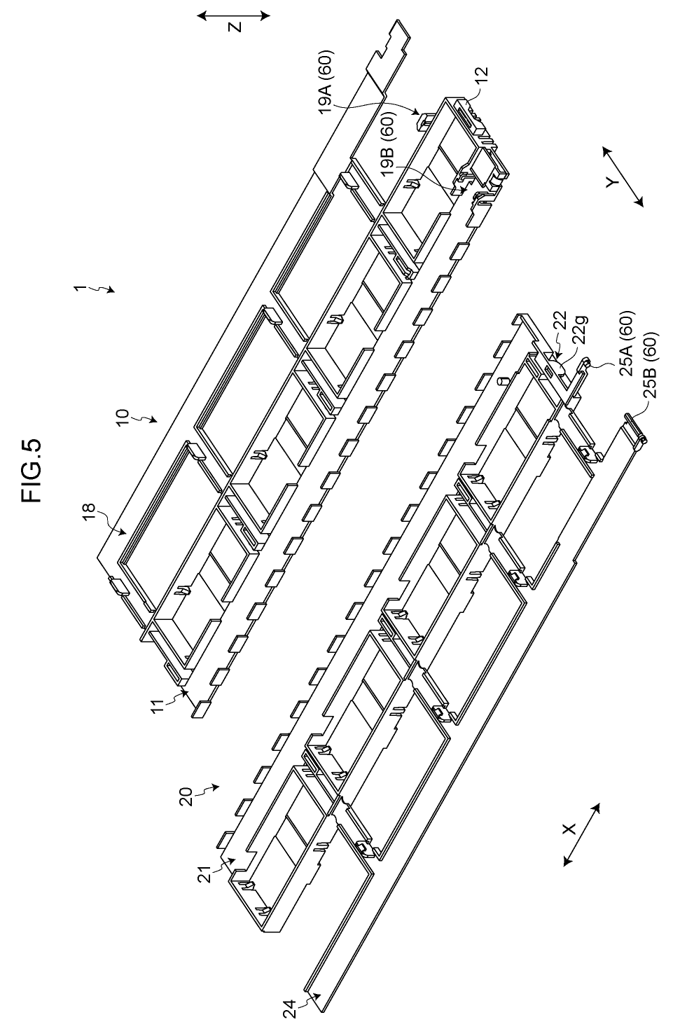

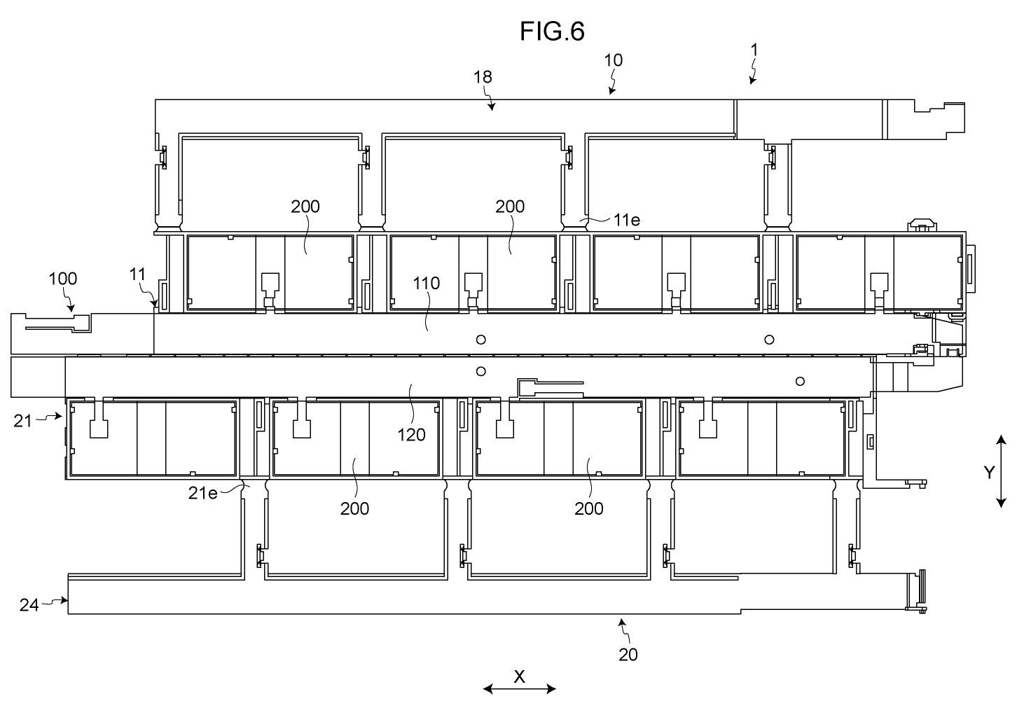

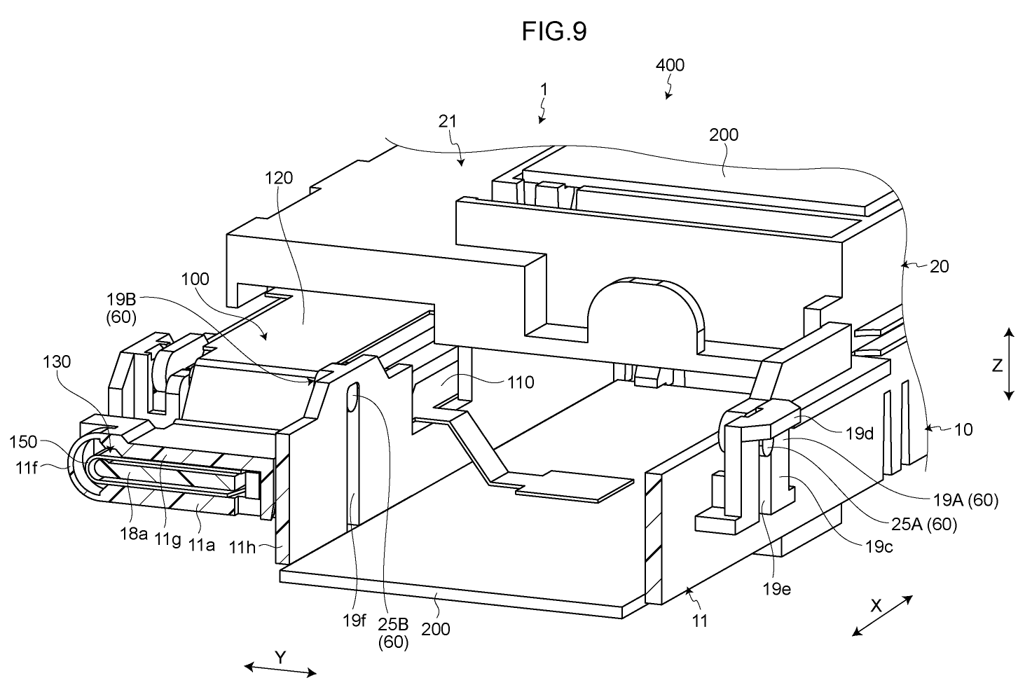

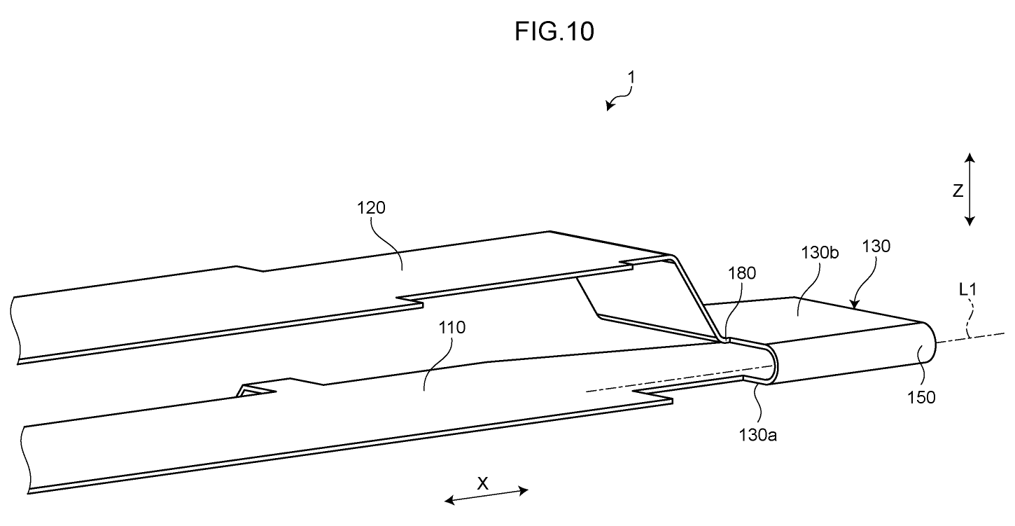

An embodiment will be described with reference to FIGS. 1 to 17. The present embodiment relates to a wire harness. FIG. 1 is a perspective view of a wire harness according to the embodiment, FIG. 2 is a perspective view of a flat wiring member according to the embodiment, FIG. 3 is a plan view of the flat wiring member according to the embodiment, FIG. 4 is a plan view of a case according to the embodiment, FIG. 5 is a perspective view of a case according to the embodiment, FIGS. 6 to 8 are plan views of the wire harness according to the embodiment, FIG. 9 is a cross-sectional view of the wire harness according to the embodiment, and FIG. 10 is a perspective view of the flat wiring member according to the embodiment.

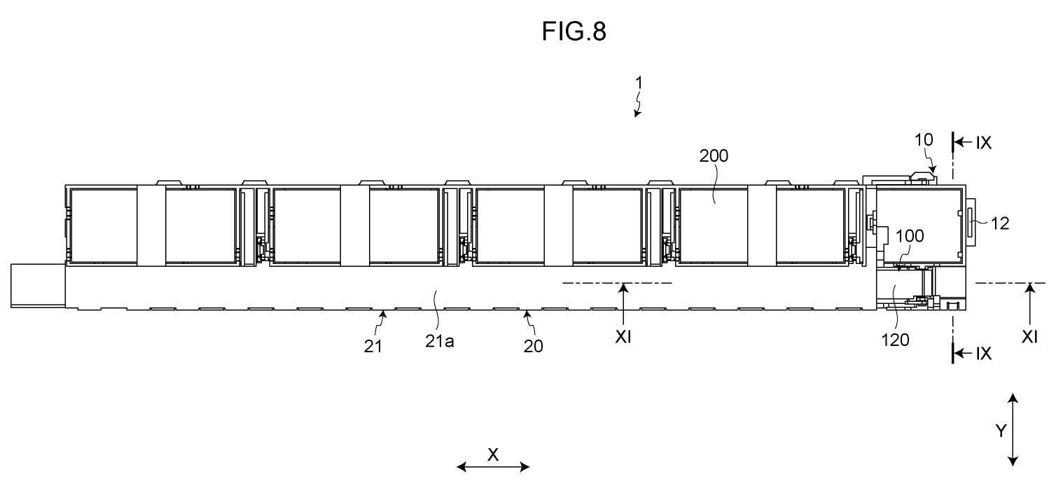

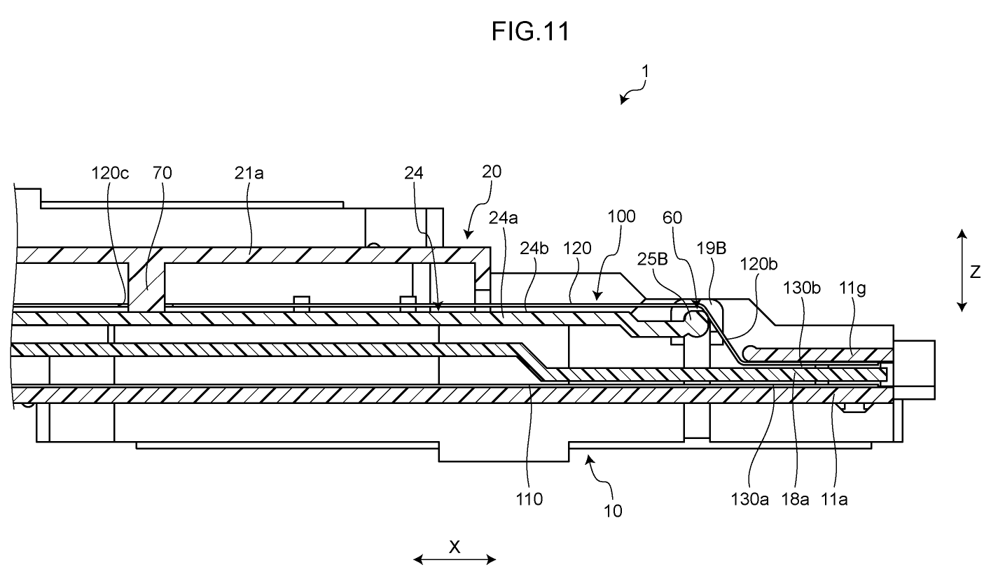

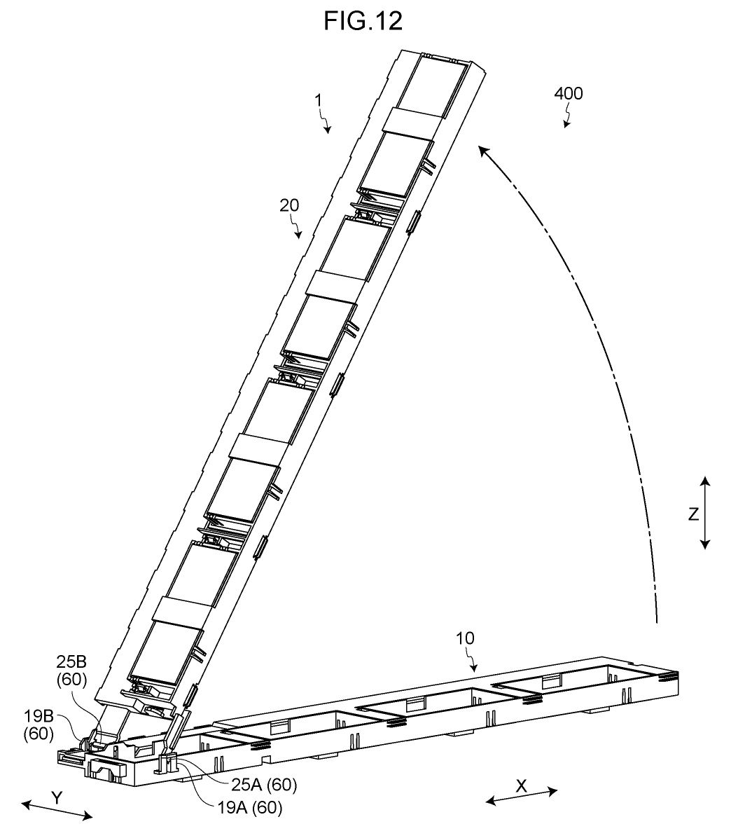

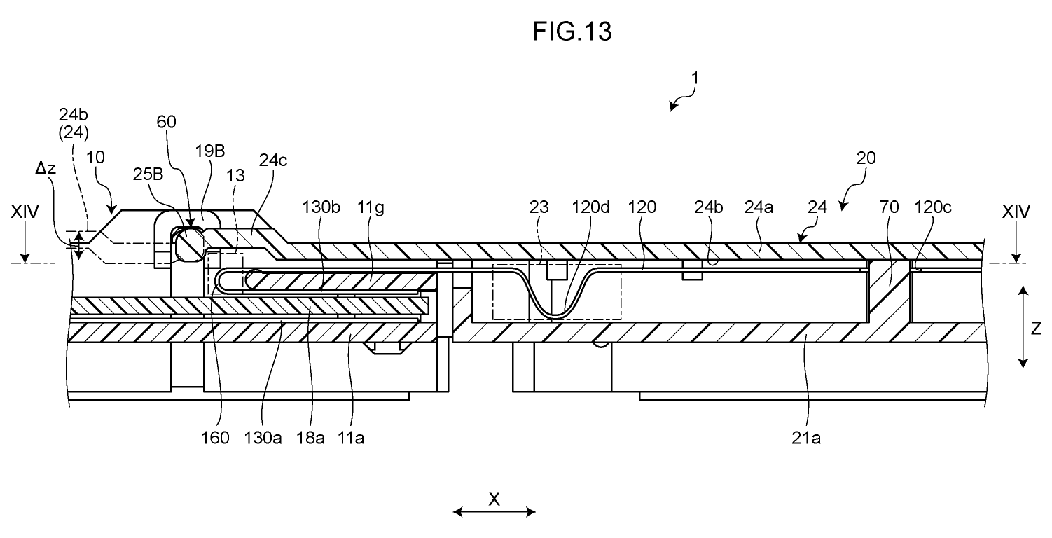

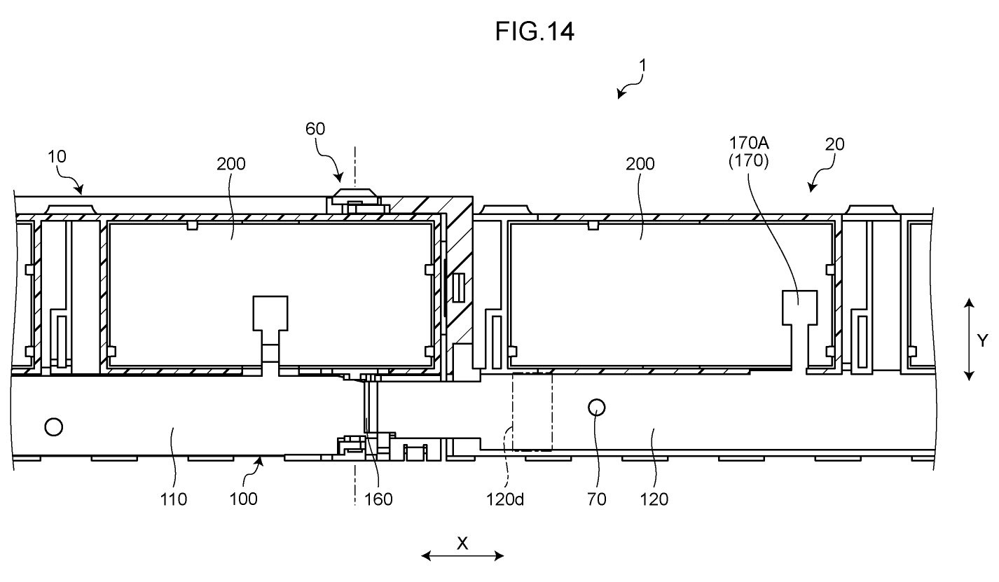

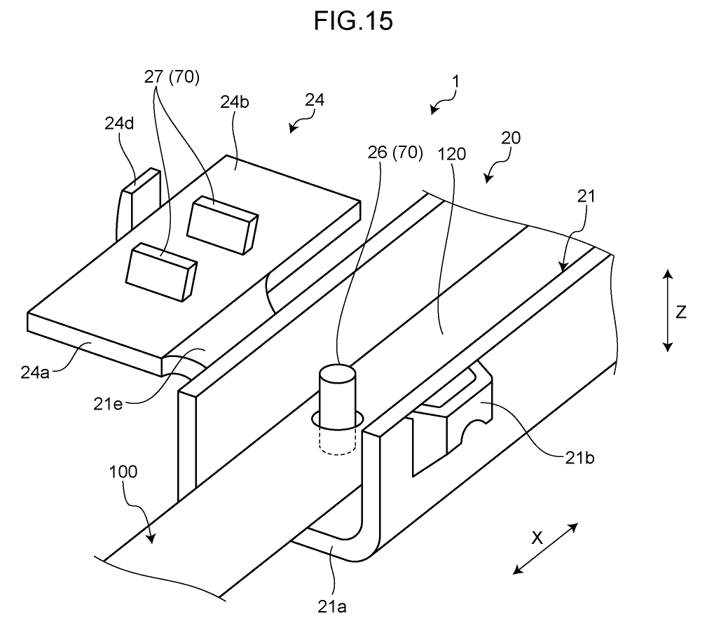

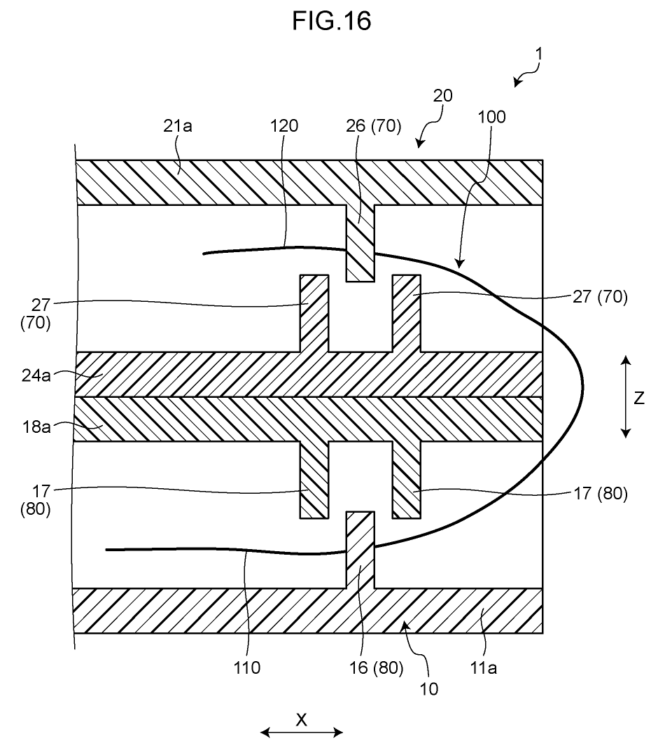

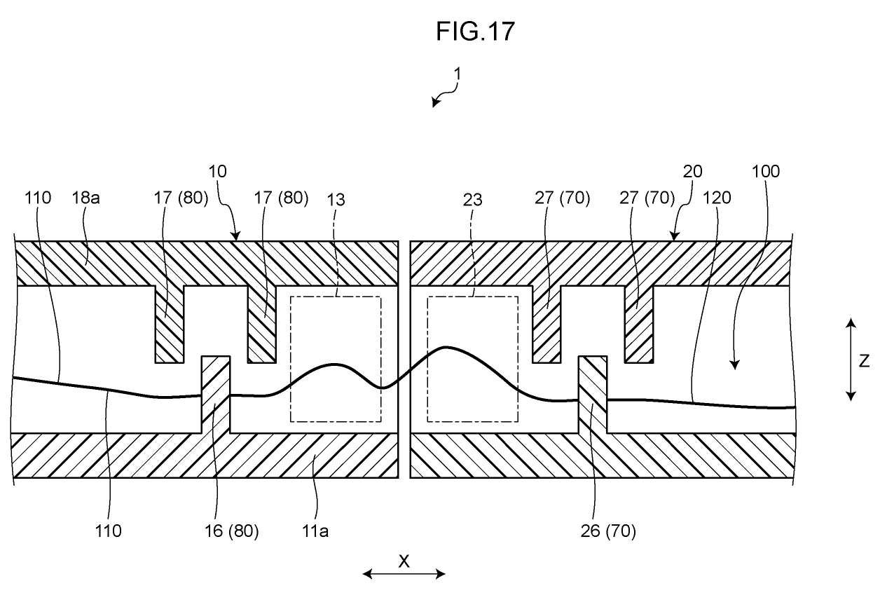

FIG. 11 is a cross-sectional view of the wire harness according to the embodiment, FIG. 12 is a perspective view illustrating the second rotation step, FIGS. 13 and 14 are cross-sectional views of the wire harness according to the embodiment, FIG. 15 is a perspective view illustrating an example of the holding structure according to the embodiment, and FIGS. 16 and 17 are cross-sectional views illustrating an example of the holding structure according to the embodiment. FIG. 9 illustrates a cross section taken along line IX-IX in FIG. 8. FIG. 11 illustrates a cross section taken along line XI-XI of FIG. 8. FIG. 13 illustrates a cross section taken along line XIII-XIII of FIG. 1. FIG. 14 illustrates a cross section taken along line XIV-XIV in FIG. 13.

As illustrated in FIG. 1, a wire harness 1 of the embodiment includes a flat wiring member 100, a first case 10, and a second case 20. As described below, the first case 10 and the second case 20 of the present embodiment can transform the flat wiring member 100 formed in a U shape into a straight line shape and hold the transformed flat wiring member 100. The first case 10 and the second case 20 are configured to engage with each other while holding the flat wiring member 100 having a straight line shape. The flat wiring member 100 in FIG. 1 is held in a straight line shape by the two cases 10 and 20.

FIG. 2 illustrates a main part of the flat wiring member 100 held in a straight line shape as illustrated in FIG. 1. FIG. 3 illustrates the U-shaped flat wiring member 100 before being transformed into a straight line shape. The flat wiring member 100 is, for example, a flexible printed circuit board (FPC). The flat wiring member 100 of the present embodiment is disposed in a battery module and detects the voltage and temperature of the battery cell of the battery module.

When the flat wiring member 100 is an FPC, the flat wiring member 100 includes a base film, a conductive layer, and a coverlay. The conductive layer is sandwiched and protected by the base film and the coverlay. The conductive layer is, for example, a conductive metal foil, and has a circuit pattern including a plurality of detection lines 140. The flat wiring member 100 has flexibility and can be bent to be wired.

The flat wiring member 100 illustrated in FIG. 3 has a substantially U shape in plan view. The flat wiring member 100 includes a first portion 110, a second portion 120, and an intermediate portion 130. The first portion 110 and the second portion 120 in plan view have substantially rectangular shapes. The flat wiring member 100 includes a slit 100s formed between the first portion 110 and the second portion 120.

The intermediate portion 130 connects an end of the first portion 110 having a straight line shape and an end of the second portion 120 having a straight line shape to each other. The intermediate portion 130 in plan view has a substantially trapezoidal shape. The intermediate portion 130 has a tapered shape whose width narrows as being farther away from the first portion 110 and the second portion 120 in the extending direction X. The extending direction X is a direction in which the first portion 110 extends and is a longitudinal direction of the first portion 110. In the flat wiring member 100 having an initial shape before transformation, the first portion 110 and the second portion 120 extend in the same extending direction X and are aligned in a width direction Y. The width direction Y is a direction orthogonal to the extending direction X, and is a width direction of the first portion 110 and the second portion 120.

The flat wiring member 100 of the present embodiment has a branch portion 170 connected to a busbar 200. The branch portion 170 extends in the width direction Y from the first portion 110 and the second portion 120. The distal end of the branch portion 170 is connected to the busbar 200 by solder, etc.

FIGS. 4 and 5 illustrate the first case 10 and the second case 20 of the present embodiment. The first case 10 and the second case 20 are molded using an insulating synthetic resin, for example. The first case 10 includes a main body 11 and a cover 18. The main body 11 and the cover 18 are integrally molded, for example. In the first case 10 of the present embodiment, the main body 11 and the cover 18 are connected to each other via a hinge portion 11e. The main body 11 includes a support wall 11a that supports the first portion 110 of the flat wiring member 100. The support wall 11a is formed in a straight line shape in the extending direction X. The cover 18 includes a facing wall 18a that covers the support wall 11a. The first portion 110 of the flat wiring member 100 is accommodated and held between the support wall 11a and the facing wall 18a.

At an end of the main body 11 in the extending direction X, there are provided a first shaft support portion 19A and a second shaft support portion 19B. The first shaft support portion 19A rotatably supports a first rotation shaft 25A of the second case 20. The second shaft support portion 19B rotatably supports a second rotation shaft 25B of the second case 20.

The second case 20 according to the embodiment includes a main body 21 and a cover 24. The main body 21 and the cover 24 are integrally molded, for example. In the second case 20 of the present embodiment, the main body 21 and the cover 24 are connected to each other via a hinge portion 21e. The main body 21 includes a support wall 21a that supports the second portion 120 of the flat wiring member 100. The support wall 21a is formed in a straight line shape in the extending direction X. The cover 24 includes a facing wall 24a that covers the support wall 21a. The second portion 120 of the flat wiring member 100 is accommodated and held between the support wall 21a and the facing wall 24a.

At an end of the main body 21 in the extending direction X, there is provided a first rotation shaft 25A. At an end of the cover 24 in the extending direction X, there is provided a second rotation shaft 25B. The first rotation shaft 25A protrudes in the width direction Y from the side surface of the main body 21. The second rotation shaft 25B extends in the width direction Y so as to cross the end of the cover 24. Both ends of the second rotation shaft 25B are supported by the second shaft support portion 19B.

In the wire harness 1 according to the embodiment, the two shaft support portions 19A and 19B of the first case 10 and the two rotation shafts 25A and 25B of the second case 20 constitute a rotating structure 60. The rotating structure 60 enables relative rotation of the two cases 10 and 20 as illustrated in FIG. 12.

As illustrated in FIG. 5, the first case 10 includes a first engagement portion 12, and the second case 20 includes a second engagement portion 22. The first engagement portion 12 is disposed at an end of the main body 11 in the extending direction X. The second engagement portion 22 is disposed at an end of the main body 21 in the extending direction X. The two engagement portions 12 and 22 are engaged with each other in a second relative position illustrated in FIG. 1.

FIG. 6 illustrates the flat wiring member 100 assembled to the first case 10 and the second case 20. The first case 10 and the second case 20 illustrated in FIGS. 4 and 6 are aligned in the width direction Y. In the present specification, regarding the first case 10 and the second case 20, a relative position in which the two cases 10 and 20 are aligned in the width direction Y is denoted as a first relative position. As illustrated in FIG. 4, when the two cases 10 and 20 are disposed in the first relative position, the support wall 11a of the first case 10 and the support wall 21a of the second case 20 are aligned in the width direction Y.

The first portion 110 of the flat wiring member 100 is accommodated in the main body 11 of the first case 10 and is supported by the support wall 11a. The step of accommodating the first portion 110 in the first case 10 is executed by an operator, for example. The second portion 120 of the flat wiring member 100 is accommodated in the main body 21 of the second case 20 and is supported by the support wall 21a. The step of accommodating the second portion 120 in the second case 20 is executed by an operator, for example. The two accommodating steps are executed in a state where the two cases 10 and 20 are held by a jig plate, for example.

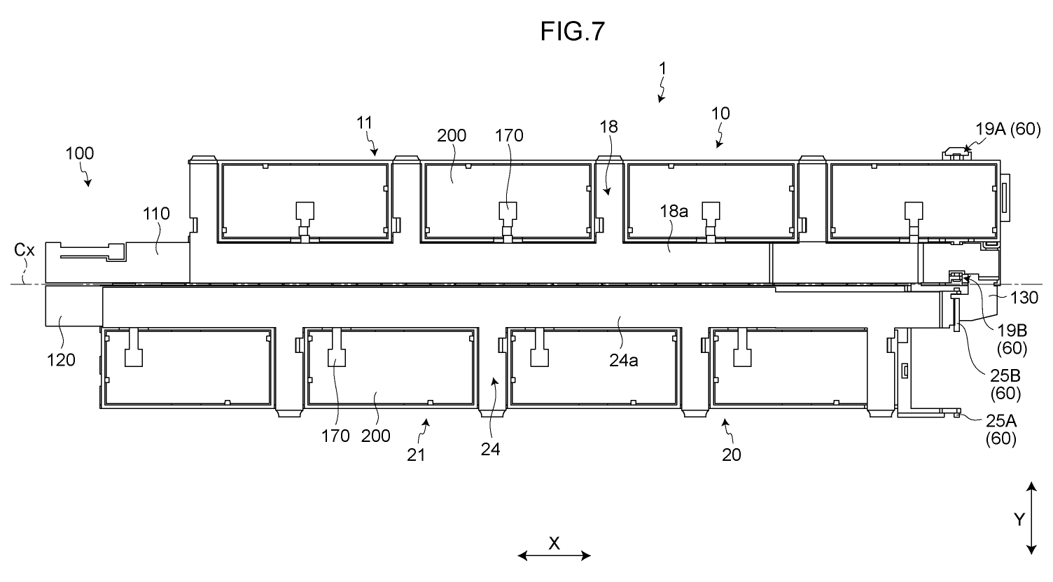

When the flat wiring member 100 has been accommodated in the two cases 10 and 20, a closing step of closing the covers 18 and 24 is executed. In the closing step, the cover 18 of the first case 10 is assembled to the main body 11 while bending the hinge portion 11e. In the closing step, the cover 24 of the second case 20 is assembled to the main body 21 while bending the hinge portion 21e. The two closing steps are executed by an operator, for example. FIG. 7 illustrates a state where the covers 18 and 24 are closed. The facing wall 18a of the cover 18 covers the first portion 110 of the flat wiring member 100. The facing wall 24a of the cover 24 covers the second portion 120 of the flat wiring member 100.

In the state illustrated in FIG. 7, a first rotation step of rotating the second case 20 relative to the first case 10 is executed. In the first rotation step, the second case 20 is rotated with respect to the first case 10 about a rotation axis Cx illustrated in FIG. 7 as a rotation center. The rotation axis Cx is a straight line extending in the extending direction X between the two covers 18 and 24, for example. The rotation at this time may be executed by using a jig plate, for example. In this case, the jig plate may include: a main body that supports the first case 10; and a support member that supports the second case 20. The support member is supported by the main body so as to be rotatable about the rotation axis Cx as a rotation center.

The second case 20 is rotated relative to the first case 10 about the rotation axis Cx as a rotation center, and the second case 20 is overlapped with the first case 10. This allows the second portion 120 of the flat wiring member 100 to overlap with the first portion 110 and face the first portion 110.

FIG. 8 illustrates a state where the first rotation step is completed and the second case 20 is overlapped with the first case 10. In the present specification, with respect to the first case 10 and the second case 20, a relative position in which the two cases 10 and 20 overlap in the height direction Z is denoted as an intermediate relative position. In the intermediate relative position, the second portion 120 of the flat wiring member 100 overlaps with the first portion 110 and faces the first portion 110. Note that the height direction Z is a direction orthogonal to both the extending direction X and the width direction Y.

Since the two cases 10 and 20 rotate about the rotation axis Cx and are positioned in the intermediate relative position, the intermediate portion 130 of the flat wiring member 100 is bent along the rotation axis Cx. FIG. 9 illustrates a cross section taken along line IX-IX of FIG. 8, and FIG. 10 illustrates the flat wiring member 100 in the state of FIG. 8. As illustrated in FIGS. 9 and 10, a first folded portion 150 is formed in the intermediate portion 130 of the flat wiring member 100.

In the first folded portion 150, the intermediate portion 130 is folded along a folding line L1 in the extending direction X. The folding line L1 is a straight line extending in the extending direction X between the two covers 18 and 24, for example. The intermediate portion 130 includes: a first region 130a connected to the first portion 110; and a second region 130b connected to the second portion 120. The intermediate portion 130 is folded back such that the first region 130a and the second region 130b face each other in the height direction Z.

As illustrated in FIG. 9, the first case 10 includes a protective cover 11g that protects the intermediate portion 130 of the flat wiring member 100. The protective cover 11g is connected to the support wall 11a via a hinge portion 11f. The protective cover 11g is engaged with the support wall 11a after the first rotation step is performed. The first case 10 accommodates the intermediate portion 130 folded back in a U shape between the support wall 11a and the protective cover 11g. The facing wall 18a of the cover 18 is sandwiched inside the folded intermediate portion 130. The hinge portion 11f covers the first folded portion 150 to protect the first folded portion 150.

As illustrated in FIG. 11, when the two cases 10 and 20 are positioned in the intermediate relative position, the second portion 120 extends along a support surface 24b. The support surface 24b is a surface included in the facing wall 24a of the cover 24, and faces the support wall 21a. The support surface 24b supports the second portion 120 and allows the second portion 120 to extend in the extending direction X.

As illustrated in FIG. 11, an inclined portion 120b is formed in the second portion 120. The inclined portion 120b is formed in a portion adjacent to the protective cover 11g of the first case 10. The inclined portion 120b is inclined with respect to the height direction Z and extends from the facing wall 18a of the first case 10 to the support surface 24b of the second case 20. That is, the inclined portion 120b is formed in accordance with the height difference between the two facing walls 18a and 24a in the height direction Z.

As illustrated in FIG. 11, the second case 20 includes a holding structure 70 that holds the second portion 120 of the flat wiring member 100. The illustrated holding structure 70 is a pillar portion protruding from the support wall 21a of the second case 20 toward the facing wall 24a. The holding structure 70 may be configured to come into contact with the support surface 24b. The holding structure 70 of the present embodiment has a columnar shape. The holding structure 70 is inserted into a through hole 120c of the second portion 120. The holding structure 70 can restrict the movement of the second portion 120 relative to the second case 20. The holding structure 70 restricts the movement of the second portion 120 in the extending direction X relative to the second case 20, for example.

When the first case 10 and the second case 20 are positioned in the intermediate relative position, the two cases 10 and 20 are coupled to each other by the rotating structure 60. As illustrated in FIG. 9, the first rotation shaft 25A of the second case 20 is rotatably supported by the first shaft support portion 19A of the first case 10. The first shaft support portion 19A includes: a piece portion 19c erected in the height direction Z; and a locking portion 19d. The piece portion 19c has a slit 19e extending in the height direction Z. The end of the first rotation shaft 25A is inserted into the slit 19e and locked by the locking portion 19d.

The second rotation shaft 25B of the second case 20 is rotatably supported by the second shaft support portion 19B of the first case 10. The second shaft support portion 19B includes a slit 19f provided in a side wall 11h. The side wall 11h is disposed on both sides in the width direction Y with respect to the support wall 11a. The end of the second rotation shaft 25B is inserted into the slit 19f and rotatably supported by the side wall 11h. By inserting the two rotation shafts 25A and 25B respectively into the two shaft support portions 19A and 19B, the first case 10 and the second case 20 are rotatably coupled to each other. This constitutes a busbar module 400. The busbar module 400 includes a plurality of busbars 200 and the wire harness 1 of the embodiment.

FIG. 12 is a diagram illustrating the second rotation step. The second rotation step is executed in a factory in which the busbar module 400 is assembled to a vehicle, etc., for example. As illustrated in FIG. 12, in the second rotation step, the second case 20 is rotated relative to the first case 10 from an intermediate relative position toward a second relative position to be described below. In the second rotation step, the second case 20 rotates relative to the first case 10 about the center axis of the two rotation shafts 25A and 25B as a rotation center.

FIG. 1 illustrates a state where the second rotation step is completed and the two cases 10 and 20 are positioned in the second relative position. In the second relative position, the first case 10 and the second case 20 are aligned in a straight line shape in the extending direction X. In this state, the first portion 110 and the second portion 120 of the flat wiring member 100 are aligned in a straight line shape. In other words, the second portion 120 is positioned on an extension line of the first portion 110 in plan view. In addition, the plurality of busbars 200 are aligned in a straight line shape in the extending direction X. The cover 18 of the first case 10 covers the first portion 110 by the facing wall 18a to protect the first portion 110. The cover 24 of the second case 20 covers the second portion 120 by the facing wall 24a to protect the second portion 120.

The second rotation step is executed to form a second folded portion 160 in the flat wiring member 100. As illustrated in FIGS. 2 and 13, the second folded portion 160 is a portion folded along a folding line L2 orthogonal to the extending direction X. In the second folded portion 160, the second portion 120 is folded along the folding line L2 such that a part of the second portion 120 overlaps with the intermediate portion 130. The folding line L2 of the present embodiment is a straight line extending in the width direction Y. When the second folded portion 160 is formed, the second region 130b of the intermediate portion 130 and a proximal end 120a of the second portion 120 face each other. The proximal end 120a is an end of the second portion 120 on a side close to the intermediate portion 130.

FIG. 13 illustrates a cross section taken along line XIII-XIII of FIG. 1. That is, the cross section of FIG. 13 is a cross section in a state where the two cases 10 and 20 are positioned in the second relative position. As illustrated in FIG. 13, the second case 20 includes a space portion 23 that absorbs an extra length of the flat wiring member 100. The space portion 23 is configured to be able to absorb an extra length that occurs in the second portion 120 of the flat wiring member 100. The second portion 120 illustrated in FIG. 13 includes a curved portion 120d. The curved portion 120d is a portion formed by an extra length that occurs in the second portion 120, and is curved toward the height direction Z.

The space portion 23 is a space portion between the support wall 21a and the facing wall 24a in the second case 20. That is, there is provided, between the support wall 21a and the facing wall 24a, the space portion 23 capable of accommodating the curved portion 120d that occurs in the second portion 120. The space portion 23 is disposed between the holding structure 70 and the rotating structure 60. As illustrated in FIG. 13, the space portion 23 is disposed between the holding structure 70 and the second rotation shaft 25B, in the second case 20. The wire harness 1 of the present embodiment includes the space portion 23 that absorbs the curved portion 120d that occurs in the second rotation step. Because of this, as described below, an unnecessary reaction force is less likely to occur in the flat wiring member 100.

First, one reason of occurrence of the curved portion 120d will be described. In FIG. 13, the position of the support surface 24b in the intermediate relative position is indicated by a one-dot chain line. A height difference ΔZ illustrated in FIG. 13 is a height difference of the support surface 24b occurring between the intermediate relative position and the second relative position. Due to the height difference ΔZ, the curved portion 120d occurs in the second rotation step. As illustrated in FIG. 11, in the intermediate relative position, the second portion 120 extends along the support surface 24b. In this state, in the second rotation step, the support surface 24b rotates relative to the first case 10 while supporting the second portion 120. At this time, an extra length occurs in the second portion 120 by the height difference ΔZ illustrated in FIG. 13 as one reason.

When an extra length occurs in the second portion 120 in the second rotation step, a reaction force would be generated in the second portion 120 without the presence of the space portion 23 that absorbs the extra length. This reaction force is a force of releasing the extra length, and is a force in the longitudinal direction of the second portion 120, for example. It is not desirable that the second portion 120 moves relative to the second case 20 by the reaction force. For example, when the second portion 120 moves with respect to the busbar 200 held by the second case 20, an unnecessary stress might be generated at the boundary portion between the branch portion 170 and the second portion 120.

In contrast, the wire harness 1 of the present embodiment includes the space portion 23 that absorbs the extra length of the second portion 120. This suppresses generation of the reaction force, and unnecessary stress is less likely to occur in the flat wiring member 100. As illustrated in FIG. 13, the curved portion 120d is formed on the first case 10 side with respect to the holding structure 70 in the extending direction X. The space portion 23 is located on the side of the first case 10 with respect to the holding structure 70, making it possible to accommodate the curved portion 120d and absorb the extra length of the second portion 120.

Note that a part of the extra length that occurs in the second portion 120 may be absorbed by a space portion 13 in the vicinity of the rotating structure 60. The space portion 13 is a space portion between the facing wall 24a of the second case 20 and the facing wall 18a of the first case 10. The space portion 13 is located between the protective cover 11g of the first case 10 and the second rotation shaft 25B of the second case 20. The facing wall 24a has a protrusion 24c that forms the space portion 13. The protrusion 24c is adjacent to the second rotation shaft 25B and protrudes toward the height direction Z so as to be away from the facing wall 18a.

As illustrated in FIG. 14, the holding structure 70 is disposed on the rotating structure 60 side with respect to a first branch portion 170A. The first branch portion 170A is the branch portion 170 disposed in the second portion 120, and is located closest to the rotating structure 60 in the extending direction X. In other words, the first branch portion 170A is the branch portion 170 located closest to the second folded portion 160 among the branch portions 170 connected to the second portion 120. The holding structure 70 can protect the branch portion 170 by restricting the movement of the second portion 120 relative to the second case 20.

Note that the holding structure 70 of the second case 20 may be configured as described with reference to FIGS. 15 to 17. The holding structure 70 illustrated in FIG. 15 includes: a pillar portion 26 provided on the main body 21 of the second case 20; and a projection 27 provided on the cover 24. The pillar portion 26 protrudes from the support wall 21a toward the height direction Z. The pillar portion 26 has a columnar shape, for example. The pillar portion 26 is inserted into the second portion 120 of the flat wiring member 100.

The projection 27 is disposed on the facing wall 24a of the cover 24. The projection 27 protrudes from the support surface 24b. The illustrated cover 24 has two projections 27. The two projections 27 are disposed on both sides in the extending direction X with respect to the pillar portion 26. The cover 24 includes an engagement portion 24d. The main body 21 includes an engagement portion 21b corresponding to the engagement portion 24d. By engaging the engagement portions 21b and 24d to each other, the cover 24 is fixed to the main body 21.

FIG. 16 illustrates a state where the cover 24 is closed and the two cases 10 and 20 are positioned in the intermediate relative position. When the cover 24 is closed, the distal end of the pillar portion 26 is inserted between the two projections 27. The projection 27 supports the second portion 120 so that the pillar portion 26 does not come out of the second portion 120.

As illustrated in FIG. 16, the first case 10 may include a holding structure 80. The holding structure 80 of the first case 10 includes a pillar portion 16 and a projection 17. The pillar portion 16 protrudes from the support wall 11a toward the height direction Z. The pillar portion 16 has a columnar shape, for example. The pillar portion 16 is inserted into the first portion 110 of the flat wiring member 100.

The projection 17 is disposed on the facing wall 18a of the cover 18. As illustrated in FIG. 16, in a state where the cover 18 is closed, the projection 17 protrudes from the facing wall 18a toward the support wall 11a. The illustrated cover 18 has two projections 17. The two projections 17 are disposed on both sides in the extending direction X with respect to the pillar portion 16. When the cover 18 is closed, the distal end of the pillar portion 16 is inserted between the two projections 17. The projection 17 supports the first portion 110 so that the pillar portion 16 does not come out of the first portion 110.

Note that the second portion 120 need not have a through hole through which the pillar portion 26 of the holding structure 70 is inserted. In this case, the holding structure 70 can sandwich and hold the second portion 120 by the pillar portion 26 and the two projections 27. Similarly, the holding structure 80 of the first case 10 may sandwich and hold the first portion 110 by the pillar portion 16 and the two projections 17.

As described above, the wire harness 1 of the present embodiment includes the flat wiring member 100, the first case 10, the second case 20, the rotating structure 60, and the space portion 23 provided in the second case 20. The flat wiring member 100 is formed in a U shape including the first portion 110 having a straight line shape, the second portion 120 having a straight line shape, and the intermediate portion 130 connecting an end of the first portion 110 and an end of the second portion 120 to each other. The first case 10 holds the first portion 110, and the second case 20 holds the second portion 120. The rotating structure 60 couples the first case 10 and the second case 20 to each other so as to be able to rotate relative to each other.

The first case 10 and the second case 20 can be engaged with each other in a state where the flat wiring member 100 has a straight line shape. In the flat wiring member 100 having a straight line shape, the second portion 120 extends on the extension line of the first portion 110 in plan view. The flat wiring member 100 having a straight line shape includes the first folded portion 150 and the second folded portion 160. In the first folded portion 150, the intermediate portion 130 is folded along a folding line L1 in the extending direction X in which the first portion 110 extends. In the second folded portion 160, the second portion 120 is folded along the folding line L2 orthogonal to the extending direction X so that a part of the second portion 120 overlaps the intermediate portion 130.

The rotating structure 60 is configured to form the second folded portion 160 in the second portion 120 by rotating the first case 10 and the second case 20 relative to each other. The space portion 23 accommodates an extra length that occurs in the second portion 120 when the first case 10 and the second case 20 rotate relative to each other while forming the second folded portion 160. With the wire harness 1 of the present embodiment, the flat wiring member 100 formed in the U shape can be elongated into a straight line shape, and the stress associated with the occurrence of the extra length can be relaxed.

The second case 20 of the present embodiment includes the holding structure 70. The holding structure 70 is a structure that holds the second portion 120 and restricts the movement of the second portion 120 relative to the second case 20. The space portion 23 of the second case 20 is disposed between the holding structure 70 and the rotating structure 60. The space portion 23 arranged in this manner can appropriately accommodate the extra length that occurs.

The rotating structure 60 of the present embodiment is configured to couple the first case 10 and the second case 20 to each other in a state where the first folded portion 150 is formed in the flat wiring member 100. In this case, the first case 10 and the second case 20 are coupled to each other by the rotating structure 60 while holding the flat wiring member 100 including the first folded portion 150. Thereafter, the first case 10 and the second case 20 rotate relative to each other to form the second folded portion 160 in the flat wiring member 100. Note that the two cases 10 and 20 may be coupled to each other by the rotating structure 60 while forming the first folded portion 150 in the flat wiring member 100.

The contents disclosed in the above embodiment can be executed in appropriate combination with each other.

In the wire harness according to the present embodiment, the rotating structure is configured to form the second folded portion in the second portion by rotating the first case and the second case relative to each other, and the space portion accommodates an extra length that occurs in the second portion when the first case and the second case rotate relative to each other while forming the second folded portion. According to the wire harness of the present embodiment, there is an effect that a flat wiring member formed in a U shape can be elongated into a straight line shape and that the stress associated with occurrence of an extra length can be relaxed.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wire harness comprising:
a flat wiring member formed in a U shape, the flat wiring member including a first portion having a straight line shape, a second portion having a straight line shape, and an intermediate portion connecting an end of the first portion and an end of the second portion to each other;
a first case that holds the first portion;
a second case that holds the second portion;
a rotating structure that couples the first case and the second case to each other so as to be able to rotate relative to each other; and
a space portion provided in the second case, wherein
the first case and the second case can be engaged with each other in a state where the flat wiring member has a straight line shape,
the flat wiring member having a straight line shape has a configuration in which the second portion extends on an extension line of the first portion in plan view,
the flat wiring member having a straight line shape includes a first folded portion and a second folded portion,
the intermediate portion is folded along a folding line in the first folded portion, the folding line extending in an extending direction in which the first portion extends,
the second portion is folded, in the second folded portion, along a folding line orthogonal to the extending direction so as to allow a part of the second portion to overlap with the intermediate portion,
the rotating structure is configured to form the second folded portion in the second portion by rotating the first case and the second case relative to each other, and
the space portion accommodates an extra length that occurs in the second portion when the first case and the second case rotate relative to each other while forming the second folded portion.

2. The wire harness according to claim 1, wherein
the second case includes a holding structure that holds the second portion and restricts a movement of the second portion relative to the second case, and
the space portion is disposed between the holding structure and the rotating structure.

3. The wire harness according to claim 1, wherein
the rotating structure is configured to couple the first case and the second case to each other in a state where the first folded portion is formed in the flat wiring member.
